(19) United States
(12) Patent Application Publication
(10) Pub. No.: US 2024/0413132 A1
(43) Pub. Date: Dec. 12, 2024

(54) DISPLAY PANEL, AND DISPLAY APPARATUS HAVING DISPLAY PANEL

(71) Applicants: Yunnan Invensight Optoelectronics Technology Co., Ltd., Kunming, Yunnan (CN); BOE Technology Group Co., Ltd., Beijing (CN)

(72) Inventor: Min LIU, Beijing (CN)

(21) Appl. No.: 18/702,342

(22) PCT Filed: Apr. 26, 2023
(86) PCT No.: PCT/CN2023/090938

§ 371 Date: Apr. 18, 2024

(30) Foreign Application Priority Data
Apr. 28, 2022 (CN) 202210470751.4

(51) Int. Cl. H01L 25/075; H01L 33/58

(52) U.S. Cl. CPC H01L 25/0753; H01L 33/58

(57) ABSTRACT

A display panel, and a display apparatus having the display panel. A display region of the display panel comprises: a special-shaped display area, which comprises a first pixel group (1), wherein the first pixel group at least includes a special-shaped sub-pixel (11), the special-shaped sub-pixel comprising one special-shaped sub-pixel edge (111), and the special-shaped sub-pixel edge matching a special-shaped edge of the special-shaped display area; and a non-special-shaped display area, which comprises at least one second pixel group (2), wherein the second pixel group includes a plurality of regular sub-pixels.

### CROSS-REFERENCE TO RELATED APPLICATION

The present application is a U.S. National Phase Entry of International Application No. PCT/CN2023/090938 having an international filing date of Apr. 26, 2023, which claims priority of Chinese patent application No. 202210470751.4, filed to CNIPA on Apr. 28, 2022 and entitled “Display Panel and Display Apparatus Having Display Panel”. Contents of the above-identified applications should be construed as being incorporated into the present application by reference.

### TECHNICAL FIELD

Embodiments of the present disclosure relate to the field of display technologies, and particularly relate to a display panel and a display apparatus having the display panel.

### BACKGROUND

At present, most of silicon-based micro displays are in square design, but due to people's demand for colorful display screens, displays with various irregular edges such as round edge, arc edge, and oval edge may appear in the life of people one after another in the future. However, problems, such as jagged edge, colored edge of an irregular edge display appear along with the displays.

### SUMMARY

The following is a summary of subject matter described in the present disclosure in detail. This summary is not intended to limit the protection scope of claims.

An exemplary embodiment of the present disclosure provides a display panel, a display area of the display panel including:
an irregular display region, wherein the irregular display region includes a first pixel group, the first pixel group at least includes an irregular sub-pixel, the irregular sub-pixel includes an irregular sub-pixel edge, and the irregular sub-pixel edge is matched with an irregular edge of the irregular display region; and
a non-irregular display region, wherein the non-irregular display region includes at least one second pixel group, and the second pixel group includes multiple regular sub-pixels.

In an exemplary implementation, the irregular sub-pixel edge is parallel to the irregular edge of the irregular display region.

In an exemplary implementation, the first pixel group includes a first irregular sub-pixel and a second irregular sub-pixel

The first irregular sub-pixel and the second irregular sub-pixel are sequentially arranged along a first direction, a maximum width of the first irregular sub-pixel in the first direction is greater than a maximum width of the second irregular sub-pixel in the first direction, and a maximum length of the first irregular sub-pixel in a second direction is less than a maximum length of the second irregular sub-pixel in the second direction.

In an exemplary implementation, light emitting areas of the first irregular sub-pixel and the second irregular sub-pixel are identical.

In an exemplary implementation, light emitting colors of the first irregular sub-pixel and the second irregular sub-pixel are different from each other.

In an exemplary implementation, the first pixel group further includes a third regular sub-pixel.

The first irregular sub-pixel, the second irregular sub-pixel, and the third regular sub-pixel are sequentially arranged along the first direction, a maximum width of the third regular sub-pixel in the first direction is less than maximum widths of the first irregular sub-pixel and the second irregular sub-pixel in the first direction, and a maximum length of the third regular sub-pixel in the second direction is greater than maximum lengths of the first irregular sub-pixel and the second irregular sub-pixel in the second direction.

In an exemplary implementation, light emitting areas of the first irregular sub-pixel, the second irregular sub-pixel, and the third regular sub-pixel are identical.

In an exemplary implementation, light emitting colors of the first irregular sub-pixel, the second irregular sub-pixel, and the third regular sub-pixel are different from each other.

In an exemplary implementation, at least two of the first irregular sub-pixel, the second irregular sub-pixel, and the third regular sub-pixel have different configurations.

In an exemplary implementation, the display panel further includes a filter layer.

The first pixel group includes a first irregular sub-pixel and a second irregular sub-pixel, the first irregular sub-pixel and the second irregular sub-pixel are sequentially arranged along a first direction, a maximum width of the first irregular sub-pixel in the first direction is identical to a maximum width of the second irregular sub-pixel in the first direction, and a maximum length of the first irregular sub-pixel in a second direction is less than a maximum length of the second irregular sub-pixel in the second direction.

The filter layer includes a first irregular sub-pixel filter corresponding to the first irregular sub-pixel and a second irregular sub-pixel filter corresponding to the second irregular sub-pixel, a maximum width of the first irregular sub-pixel filter in the first direction is greater than a maximum width of the second irregular sub-pixel filter in the first direction, and a maximum length of the first irregular sub-pixel filter in the second direction is less than a maximum length of the second irregular sub-pixel filter in the second direction.

In an exemplary implementation, areas of the first irregular sub-pixel filter and the second irregular sub-pixel filter are identical.

In an exemplary implementation, the first pixel group further includes a third regular sub-pixel.

The first irregular sub-pixel, the second irregular sub-pixel, and the third regular sub-pixel are sequentially arranged along the first direction, maximum widths of the first irregular sub-pixel, the second irregular sub-pixel and the third regular sub-pixel in the first direction are all identical, and a maximum length of the third regular sub-pixel in the second direction is greater than maximum lengths of the first irregular sub-pixel and the second irregular sub-pixel in the second direction.

The filter layer further includes a third regular sub-pixel filter corresponding to the third regular sub-pixel, a maximum width of the third regular sub-pixel filter in the first direction is less than maximum widths of the first irregular sub-pixel filter and the second irregular sub-pixel filter in the first direction, and a maximum length of the third regular sub-pixel filter in the second direction is greater than maximum lengths of the first irregular sub-pixel filter and the second irregular sub-pixel filter in the second direction.

In an exemplary implementation, areas of the first irregular sub-pixel filter, the second irregular sub-pixel filter, and the third regular sub-pixel filter are identical.

In an exemplary implementation, a length of an irregular edge of the first irregular sub-pixel is greater than a maximum width of the first irregular sub-pixel in the first direction, and a length of an irregular edge of the second irregular sub-pixel is greater than a maximum width of the second irregular sub-pixel in the first direction.

In an exemplary implementation, the second pixel group includes a fourth regular sub-pixel, a fifth regular sub-pixel, and a sixth regular sub-pixel.

Maximum widths of the fourth regular sub-pixel, the fifth regular sub-pixel, and the sixth regular sub-pixel in the first direction are all identical, and maximum lengths of the fourth regular sub-pixel, the fifth regular sub-pixel and the sixth regular sub-pixel in the second direction are all identical.

In an exemplary implementation, light emitting colors of the first irregular sub-pixel, the second irregular sub-pixel, the third regular sub-pixel, the fourth regular sub-pixel, the fifth regular sub-pixel, and the sixth regular sub-pixel are formed by covering corresponding sub-pixels with filters of corresponding colors.

In an exemplary implementation, a light emitting color of the first irregular sub-pixel is formed by covering the first irregular sub-pixel with the first irregular sub-pixel filter; a light emitting color of the second irregular sub-pixel is formed by covering the second irregular sub-pixel with the second irregular sub-pixel filter; and a light emitting color of the third regular sub-pixel is formed by covering the third regular sub-pixel with the third regular sub-pixel filter.

In an exemplary implementation, the first irregular sub-pixel and the fourth regular sub-pixel are sub-pixels with the same light emitting color; the second irregular sub-pixel and the fifth regular sub-pixel are sub-pixels with the same light emitting color; and the third regular sub-pixel and the sixth regular sub-pixel are sub-pixels with the same light emitting color.

In an exemplary implementation, the light emitting color of the first irregular sub-pixel and the fourth regular sub-pixel is a first color of three primary colors; the light emitting color of the second irregular sub-pixel and the fifth regular sub-pixel is a second color of the three primary colors; and the light emitting color of the third regular sub-pixel and the sixth regular sub-pixel is a third color of the three primary colors.

An exemplary embodiment of the present disclosure further provides a display apparatus, including the display panel described in any of above embodiments.

Additional aspects and advantages of the present disclosure will be set forth in part in the following description, part of which will be apparent from the description, or may be learned through practice of the present disclosure.

### BRIEF DESCRIPTION OF DRAWINGS

FIG. 1 is a schematic diagram of a display panel according to an exemplary embodiment of the present disclosure.

FIG. 2 is a schematic diagram of a display panel according to another exemplary embodiment of the present disclosure.

FIG. 3 is a schematic diagram of a pixel arrangement of a square display.

FIG. 4 is a schematic diagram of a pixel arrangement of an irregular edge display with jags.

FIG. 5 is a schematic diagram of a pixel arrangement of a color shifting irregular edge display.

### DETAILED DESCRIPTION

Exemplary embodiments of the present disclosure are described in detail below, and in examples of the embodiments are illustrated in the drawings, in which the same or similar reference signs always denote the same or similar elements or elements having the same or similar functions. The embodiments described below with reference to the drawings are exemplary, and are merely intended to explain the present disclosure, which cannot be interpreted as a limitation on the present disclosure.

The embodiments and features in the embodiments of the present disclosure may be randomly combined with each other if there is no conflict.

In descriptions of the present disclosure, orientations or positional relationships indicated by terms “longitudinal”, “transverse”, “length”, “width”, “thickness”, “upper”, “lower”, “front”, “back”, “left”, “right”, “vertical”, “horizontal”, “top”, “bottom”, “inside”, “outside”, and the like are based on orientations or positional relationships shown in the drawings, and are only for convenience of describing the present disclosure and simplifying the description, but do not indicate or imply that a referred device or element must have a specific orientation, or is constructed and operated in a particular orientation, and therefore they should not be construed as limitations on the present disclosure.

In addition, terms “first” and “second” are used for descriptive purposes only and cannot be interpreted as indicating or implying relative importance or implicitly indicating a quantity of technical features indicated. Therefore, features defined by “first” or “second” may explicitly or implicitly include one or more of such features. In the description of the present disclosure, the meaning of “a plurality of” refers to “at least two”, such as “two” or “three”, unless otherwise explicitly defined.

According to the present disclosure, unless otherwise explicitly specified and defined, terms “mounting”, “coupling”, “connection” and “fixing” or the like should be understood in a broad sense. For example, it may be a fixed connection or a detachable connection or an integral connection; it may be a mechanical connection, an electrical connection or a communication with each other; and it may be a direct connection or an indirect connection through an intermediate medium; or it may be an internal communication between two elements or interaction between the two elements. Those of ordinary skills in the art may understand meanings of the aforementioned terms in the present disclosure according to situations.

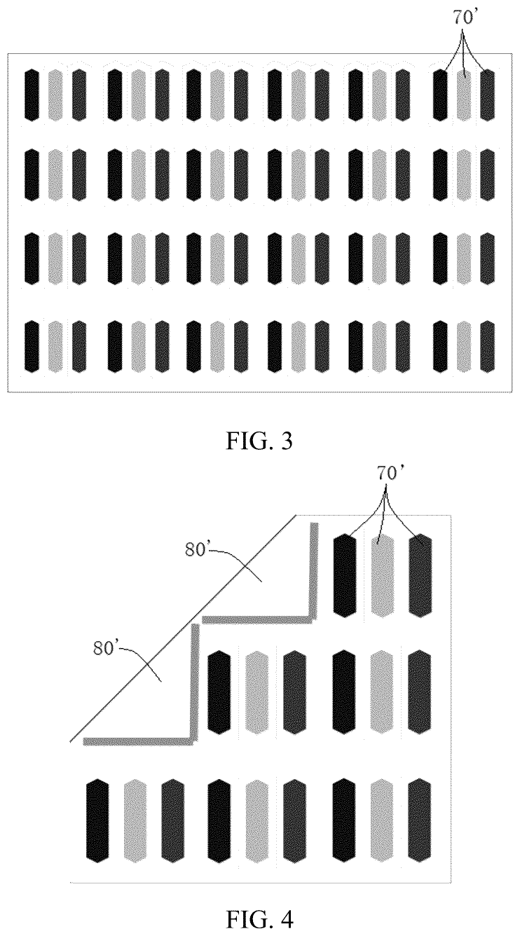

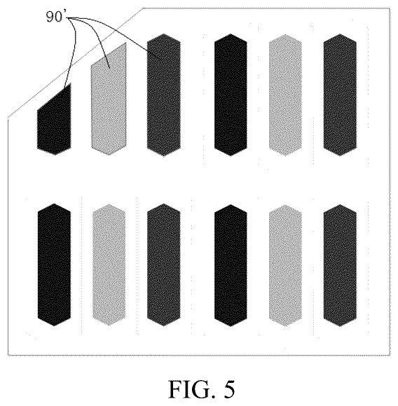

At present, most of silicon-based micro displays are in square design, and a pixel 70′ arrangement of a square display is shown in FIG. 3. Due to people's demand for colorful display screens, displays with various irregular edges such as round edge, arc edge, and oval edge may appear in the life of people one after another in the future. However, irregular edge displays are prone to problems, such as a jagged edge and a colored edge. As shown in FIG. 4, there are jags 80′ at an edge of an irregular edge display. In some technologies, in order to avoid a phenomenon of jagged edge caused by blank at an edge portion, three RGB sub-pixels 90′ are also provided in this area. As shown in FIG. 5, a shape of the sub-pixels 90′ is consistent with an edge of a display area. Since heights of three RGB sub-pixels are inconsistent, if widths of original RGB light emitting areas are still kept identical, light emitting areas of the three colors will be inconsistent, and when light emitting brightness of three primary colors are out of balance, a composite white color will be shifted, which will affect the display effect.

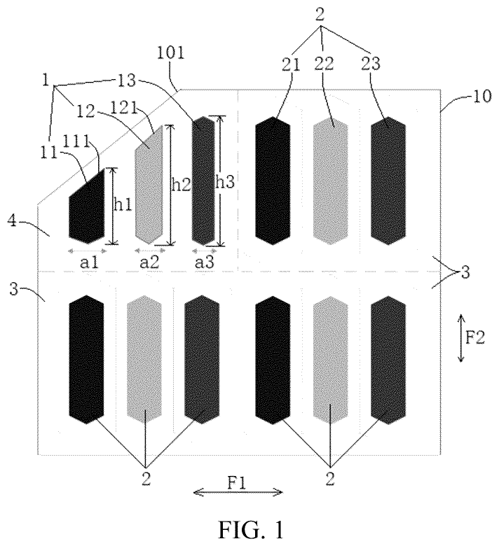

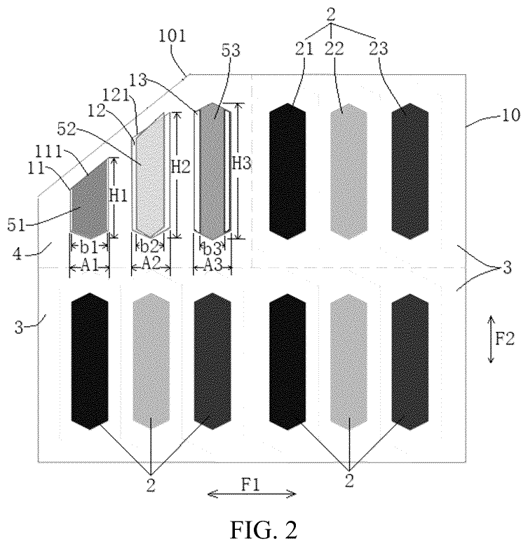

Exemplary embodiments of the present disclosure are capable of effectively eliminating problems such as jagged edge and colored edge at an irregular edge of a display area and a display panel 10 according to an exemplary embodiment of the present disclosure is described in detail below with reference to FIGS. 1-2.

Referring to FIGS. 1-2, a display area of a display panel 10 according to an exemplary embodiment of the present disclosure includes a non-irregular display region 3 and an irregular display region 4.

The irregular display region 4 may include a first pixel group 1, and the first pixel group 1 is used for displaying a picture or a video. The first pixel group 1 at least includes a irregular sub-pixel, and the irregular sub-pixel includes an irregular sub-pixel edge (e.g., a first irregular edge 111 and a second irregular edge 121 mentioned later). The irregular sub-pixel edge is matched with an irregular edge of the irregular display region 4 (i.e., an irregular display edge 101) to prevent edge jags from appearing at the irregular edge of the irregular display region 4. In other words, the display panel 10 has an irregular display edge 101. The irregular display edge 101 is divided into a portion of the irregular display region 4. The first pixel group 1 is provided in the irregular display region 4 to match the irregular sub-pixel edge with the irregular display edge 101, thereby eliminating problems such as jagged edge and colored edge at the irregular display edge 101.

The non-irregular display region 3 includes at least one second pixel group 2 and the second pixel group 2 is used for displaying a picture or a video. The second pixel group 2 includes multiple regular sub-pixels, and the regular sub-pixels are arranged according to a shape of the non-irregular display region 3 to completely fill the non-irregular display region 3, thereby ensuring that the non-irregular display region 3 has good display effect.

Shapes and sizes of the multiple regular sub-pixels mentioned above are identical. In an exemplary implementation, the regular sub-pixels may be rectangular sub-pixels, square sub-pixels and the like.

According to the display panel 10 of an exemplary embodiment of the present disclosure, the first pixel group 1 may be at least provided at the irregular display region 4 of the display panel 10 to eliminate problems such as jagged edge and colored edge at the irregular edge of the irregular display region 4, thus eliminating problems such as jagged edge and colored edge at the irregular display edge 101 of the display panel 10.

In some exemplary embodiments of the present disclosure, an irregular sub-pixel edge is parallel to an irregular edge of the irregular display region 4, thereby ensuring that irregular sub-pixels can be provided at the irregular edge of the irregular display region 4 and preventing edge jags from generating in a display area of the display panel 10.

In some exemplary embodiments of the present disclosure, referring to FIG. 1, the first pixel group 1 may include a first irregular sub-pixel 11 and a second irregular sub-pixel 12, and the first irregular sub-pixel 11 and the second irregular sub-pixel 12 are sequentially arranged along a first direction F1. A maximum width of the first irregular sub-pixel 11 in the first direction F1 is greater than a maximum width of the second irregular sub-pixel 12 in the first direction F1, and a maximum length of the first irregular sub-pixel 11 in a second direction F2 is less than a maximum length of the second irregular sub-pixel 12 in the second direction F2.

In an exemplary embodiment of the present disclosure, the first direction F1 is a horizontal direction in FIGS. 1-2 and the second direction F2 is a perpendicular direction in FIGS. 1-2.

For example, in a horizontal right direction shown in FIG. 1, the first irregular sub-pixel 11 and the second irregular sub-pixel 12 are sequentially arranged, maximum widths of the first irregular sub-pixel 11 and the second irregular sub-pixel 12 are gradually reduced, and maximum lengths of the first irregular sub-pixel 11 and the second irregular sub-pixel 12 are gradually increased. In an exemplary embodiment shown in FIG. 1, the first irregular sub-pixel 11 has a maximum length of h1 and a maximum width of a1, and the second irregular sub-pixel 12 has a maximum length of h2 and a maximum width of a2, and h1, h2, a1 and a2 satisfy the relationship: h1<h2, a1>a2.

In an exemplary implementation, light emitting areas of the first irregular sub-pixel 11 and the second irregular sub-pixel 12 are identical. Referring to FIG. 1, if h1<h2, then a1>a2, thereby ensuring that the light emitting areas of the first irregular sub-pixel 11 and the second irregular sub-pixel 12 are identical.

In an exemplary implementation, light emitting colors of the first irregular sub-pixel 11 and the second irregular sub-pixel 12 are different from each other.

In some exemplary embodiments of the present disclosure, referring to FIG. 1, the first pixel group 1 may further include a third regular sub-pixel 13. The first irregular sub-pixel 11, the second irregular sub-pixel 12, and the third regular sub-pixel 13 are sequentially arranged along the first direction F1. A maximum width of the third regular sub-pixel 13 in the first direction F1 is less than maximum widths of the first irregular sub-pixel 11 and the second irregular sub-pixel 12 in the first direction F1, and a maximum length of the third regular sub-pixel 13 in the second direction F2 is greater than maximum lengths of the first irregular sub-pixel 11 and the second irregular sub-pixel 12 in the second direction F2.

For example, in the horizontal right direction shown in FIG. 1, the first irregular sub-pixel 11, the second irregular sub-pixel 12, and the third regular sub-pixel 13 are sequentially arranged, maximum widths of the first irregular sub-pixel 11, the second irregular sub-pixel 12, and the third regular sub-pixel 13 are gradually reduced, and maximum lengths of the first irregular sub-pixel 11, the second irregular sub-pixel 12, and the third regular sub-pixel 13 are gradually increased. In an exemplary embodiment shown in FIG. 1, the first irregular sub-pixel 11 has a maximum length of h1 and a maximum width of a1, the second irregular sub-pixel 12 has a maximum length of h2 and a maximum width of a2, and the third regular sub-pixel 13 has a maximum length of h3 and a maximum width of a3. h1, h2, h3, a1, a2 and a3 satisfy the relationship: h1<h2<h3, a1>a2>a3.

In some exemplary embodiments not shown in the figures, if h1, h2, and h3 are not exactly identical, then a1, a2, and a3 are not exactly identical. For example, if h1<h2=h3, then a1>a2=a3.

In an exemplary implementation, light emitting areas of the first irregular sub-pixel 11, the second irregular sub-pixel 12, and the third regular sub-pixel 13 are identical. Referring to FIG. 1, when h1<h2<h3, a1>a2>a3, thus ensuring that the light emitting areas of the first irregular sub-pixel 11, the second irregular sub-pixel 12, and the third regular sub-pixel 13 are identical.

In an exemplary implementation, light emitting colors of the first irregular sub-pixel 11, the second irregular sub-pixel 12, and the third regular sub-pixel 13 are different from each other.

As shown in conjunction with FIG. 1, at least two of the first irregular sub-pixel 11, the second irregular sub-pixel 12, and the third regular sub-pixel 13 have different configurations so that the first pixel group 1 satisfies the display requirements of the irregular display region 4. In an exemplary implementation, maximum lengths of the first irregular sub-pixel 11, the second irregular sub-pixel 12, and the third regular sub-pixel 13 are adapted to be matched with the irregular edge of the irregular display region 4 to prevent edge jags from appearing at the irregular edge of the irregular display region 4.

In some exemplary embodiments of the present disclosure with reference to FIG. 2, the display panel 10 further includes a filter layer; the first pixel group 1 may include a first irregular sub-pixel 11 and a second irregular sub-pixel 12, and the first irregular sub-pixel 11 and the second irregular sub-pixel 12 are arranged sequentially along a first direction F1. A maximum width of the first irregular sub-pixel 11 in the first direction F1 is identical to a maximum width of the second irregular sub-pixel 12 in the first direction F1, and a maximum length of the first irregular sub-pixel 11 in a second direction F2 is less than a maximum length of the second irregular sub-pixel 12 in the second direction F2. The filter layer includes a first irregular sub-pixel filter 51 and a second irregular sub-pixel filter 52, the first irregular sub-pixel filter 51 corresponds to the first irregular sub-pixel 11, and the second irregular sub-pixel filter 52 corresponds to the second irregular sub-pixel 12. A maximum width of the first irregular sub-pixel filter 51 in the first direction F1 is greater than a maximum width of the second irregular sub-pixel filter 52 in the first direction F1, and a maximum length of the first irregular sub-pixel filter 51 in the second direction F2 is less than a maximum length of the second irregular sub-pixel filter 52 in the second direction F2.

For example, in a horizontal right direction shown in FIG. 2, the first irregular sub-pixel 11 and the second irregular sub-pixel 12 are sequentially arranged, maximum widths of the first irregular sub-pixel 11 and the second irregular sub-pixel 12 are identical, and maximum lengths of the first irregular sub-pixel 11 and the second irregular sub-pixel 12 are gradually increased. Maximum widths of the first irregular sub-pixel filter 51 and the second irregular sub-pixel filter 52 are gradually reduced and maximum lengths of the first irregular sub-pixel filter 51 and the second irregular sub-pixel filter 52 are gradually increased.

In an exemplary implementation, areas of the first irregular sub-pixel filter 51 and the second irregular sub-pixel filter 52 are identical.

In some exemplary embodiments of the present disclosure with reference to FIG. 2, the first pixel group 1 further includes a third regular sub-pixel 13, and the first irregular sub-pixel 11, the second irregular sub-pixel 12, and the third regular sub-pixel 13 are sequentially arranged along the first direction F1. Maximum widths of the first irregular sub-pixel 11, the second irregular sub-pixel 12, and the third regular sub-pixel 13 in the first direction F1 are all identical, and a maximum length of the third regular sub-pixel 13 in the second direction F2 is greater than maximum lengths of the first irregular sub-pixel 11 and the second irregular sub-pixel 12 in the second direction F2. The filter layer further includes a third regular sub-pixel filter 53, and the third regular sub-pixel filter 53 corresponds to the third regular sub-pixel 13. A maximum width of the third regular sub-pixel filter 53 in the first direction F1 is less than maximum widths of the first irregular sub-pixel filter 51 and the second irregular sub-pixel filter 52 in the first direction F1, and a maximum length of the third regular sub-pixel filter 53 in the second direction F2 is greater than maximum lengths of the first irregular sub-pixel filter 51 and the second irregular sub-pixel filter 52 in the second direction F2.

For example, in the horizontal right direction in FIG. 2, the first irregular sub-pixel 11, the second irregular sub-pixel 12, and the third regular sub-pixel 13 are sequentially arranged, maximum widths of the first irregular sub-pixel 11, the second irregular sub-pixel 12, and the third regular sub-pixel 13 are all identical, and maximum lengths of the first irregular sub-pixel 11, the second irregular sub-pixel 12, and the third regular sub-pixel 13 are gradually increased. Maximum widths of the first irregular sub-pixel filter 51, the second irregular sub-pixel filter 52, and the third regular sub-pixel filter 53 are gradually reduced and maximum lengths of the first irregular sub-pixel filter 51, the second irregular sub-pixel filter 52, and the third regular sub-pixel filter 53 are gradually increased.

In an exemplary embodiment shown in FIG. 2, the first irregular sub-pixel 11 has a maximum width of A1 and a maximum length of H1, the second irregular sub-pixel 12 has a maximum width of A2 and a maximum length of H2, and the third regular sub-pixel 13 has a maximum width of A3 and a maximum length of H3. The first irregular sub-pixel filter 51 has a width of b1 and a maximum length of H1, the second irregular sub-pixel filter 52 has a width of b2 and a maximum length of H2, and the third regular sub-pixel filter 53 has a width of b3 and a maximum length of H3. A1, A2, A3, H1, H2, H3, b1, b2 and b3 satisfy the relationship: A1=A2=A3, H1<H2<H3, b1>b2>b3, b1<A1, b2<A2, b3<A3. That is, a width of the filter is less than an opening width of the light emitting region, and a maximum length of a filter is not less than a maximum length of the corresponding irregular sub-pixel.

In an exemplary implementation, areas of the first irregular sub-pixel filter 51, the second irregular sub-pixel filter 52, and the third regular sub-pixel filter 53 are identical. Referring to FIG. 2, A1=A2=A3. If H1<H2<H3, then b1>b2>b3, ensuring that light emitting areas of the first irregular sub-pixel 11, the second irregular sub-pixel 12, and the third regular sub-pixel 13 are identical.

In some exemplary embodiments not shown, A1=A2=A3, and if H1, H2, H3 are not exactly identical, then b1, b2, b3 are not exactly identical. For example, if A1=A2=A3 and H1<H2=H3, then b1>b2−b3.

As shown in conjunction with FIG. 2, at least two of the first irregular sub-pixel filter 51, the second irregular sub-pixel filter 52, and the third regular sub-pixel filter 53 have different configurations so that the first pixel group 1 satisfies the display requirements of the irregular display region 4. In an exemplary implementation, maximum lengths of the first irregular sub-pixel filter 51, the second irregular sub-pixel filter 52, and the third regular sub-pixel filter 53 are adapted to be matched with the irregular edge of the irregular display region 4 to prevent edge jags from appearing at the irregular edge of the irregular display region 4.

In some exemplary embodiments of the present disclosure with reference to FIGS. 1-2, a length of an irregular edge of the first irregular sub-pixel 11 is greater than a maximum width of the first irregular sub-pixel 11 in the first direction F1, and a length of an irregular edge of the second irregular sub-pixel 12 is greater than a maximum width of the second irregular sub-pixel 12 in the first direction F1. This ensures that an irregular edge of an irregular sub-pixel can be parallel to an irregular edge of an irregular display region 4.

Referring to FIGS. 1-2, an irregular edge of the first irregular sub-pixel 11 is a first irregular edge 111, and an irregular edge of the second irregular sub-pixel 12 is a second irregular edge 121. In FIG. 1, a length of the first irregular edge 111 is greater than a maximum width a1 of the first irregular sub-pixel 11 in the first direction F1, and a length of the second irregular edge 121 is greater than a maximum width a2 of the second irregular sub-pixel 12 in the first direction F1. In FIG. 2, a length of the first irregular edge 111 is greater than a maximum width A1 of the first irregular sub-pixel 11 in the first direction F1, and a length of the second irregular edge 121 is greater than a maximum width A2 of the second irregular sub-pixel 12 in the first direction F1.

Referring to FIGS. 1-2, when an irregular display region 4 is a trapezoidal region, an irregular edge of the first irregular sub-pixel 11 and an irregular edge of the second irregular sub-pixel 12 are conformed with a shape of a hypotenuse waist of the trapezoidal region (i.e., shape matches), so as to ensure uniform light emitting, no color shift and no jags at the area. The first irregular edge 111 and the second irregular edge 121 are adapted to be parallel to the edge of the irregular display region 4, and in an exemplary embodiment, pixel edges of the first irregular sub-pixel 11 and the second irregular sub-pixel 12 may be as close to the edge of the irregular display region 4 as possible, preventing the irregular display region 4 from having no pixels at the edge.

In some exemplary embodiments of the present disclosure with reference to FIGS. 1-2, the second pixel group 2 may include a fourth regular sub-pixel 21, a fifth regular sub-pixel 22, a sixth regular sub-pixel 23, maximum widths of the fourth regular sub-pixel 21, the fifth regular sub-pixel 22, and the sixth regular sub-pixel 23 in the first direction F1 are all identical, and maximum lengths of the fourth regular sub-pixel 21, the fifth regular sub-pixel 22, and the sixth regular sub-pixel 23 in the second direction F2 are all identical. That is, shapes and sizes of the fourth regular sub-pixel 21, the fifth regular sub-pixel 22, and the sixth regular sub-pixel 23 are all identical.

Light emitting colors of the first irregular sub-pixel 11, the second irregular sub-pixel 12, the third regular sub-pixel 13, the fourth regular sub-pixel 21, the fifth regular sub-pixel 22, and the sixth regular sub-pixel 23 are formed by covering the corresponding sub-pixels with filters of corresponding colors. For example, a light emitting color of the first irregular sub-pixel 11 is formed by covering the first irregular sub-pixel 11 with the first irregular sub-pixel filter 51, a light emitting color of the second irregular sub-pixel 12 is formed by covering the second irregular sub-pixel 12 with the second irregular sub-pixel filter 52, and a light emitting color of the third regular sub-pixel 13 is formed by covering the third regular sub-pixel 13 with the third regular sub-pixel filter 53.

In an exemplary embodiment, the first irregular sub-pixel 11 and the fourth regular sub-pixel 21 are sub-pixels of the same light emitting color, the second irregular sub-pixel 12 and the fifth regular sub-pixel 22 are sub-pixels of the same light emitting color, and the third regular sub-pixel 13 and the sixth regular sub-pixel 23 are sub-pixels of the same light emitting color.

In an exemplary implementation, a light emitting color of the first irregular sub-pixel 11 and a light emitting color of the fourth regular sub-pixel 21 are a first color of the three primary colors (BGR, blue, green and red), a light emitting color of the second irregular sub-pixel 12 and a light emitting color of the fifth regular sub-pixel 22 are a second color of the three primary colors, and a light emitting color of the third regular sub-pixel 13 and a light emitting color of the sixth regular sub-pixel 23 are a third color of the three primary colors. That is, light emitting colors of the first irregular sub-pixel 11, the second irregular sub-pixel 12 and the third regular sub-pixel 13 are the three primary colors. Thus, when the light emitting areas of the first irregular sub-pixel 11, the second irregular sub-pixel 12, and the third regular sub-pixel 13 are identical, the light emitted by the first pixel group 1 can be guaranteed to be white light, color shift is avoided, and problem of colored edge is avoided. Light emitting color of the fourth regular sub-pixel 21, the fifth regular sub-pixel 22, and the sixth regular sub-pixel 23 are the three primary colors. Thus, when the light emitting areas of the fourth regular sub-pixel 21, the fifth regular sub-pixel 22, and the sixth regular sub-pixel 23 are identical, the light emitted by the second pixel group 2 can be guaranteed to be white light and color shift can be avoided.

In an exemplary implementation, the first irregular sub-pixel 11 and the fourth regular sub-pixel 21 are blue sub-pixels and the light emitting color of first irregular sub-pixel 11 and the fourth regular sub-pixel 21 is blue, the second irregular sub-pixel 12 and the fifth regular sub-pixel 22 are green sub-pixels and the light emitting color of the second irregular sub-pixel 12 and the fifth regular sub-pixel 22 is green, the third regular sub-pixel 13 and the sixth regular sub-pixel 23 are red sub-pixels and the light emitting color of the third regular sub-pixel 13 and the sixth regular sub-pixel 23 is red.

For a display panel 10 with an irregular display edge 101, the display panel 10 can be divided into a non-irregular display region 3 and an irregular display region 4 according to a shape of the irregular display edge 101, the irregular display edge 101 is located in the irregular display region 4, and a first pixel group 1 is arranged in the irregular display region 4. A shape of the first pixel group 1 is conformed with (or is parallel to) an irregular edge of the irregular display region 4 at a position where it contacts the irregular edge of the irregular display region 4, thereby ensuring that display effect at the irregular edge of the irregular display region 4 is the same as display effect at the central area, and the same as display effect of the non-irregular display region 3, and a phenomenon of jagged edge is eliminated. In some exemplary embodiments, the so-called “irregular display edge 101” refers to a display edge that may be a round edge, an arc edge, and an oval edge, or the like in a variety of shapes.

In an exemplary implementation, the first pixel group 1 may be provided at the non-irregular display region 3.

In some exemplary embodiments of the present disclosure, an encapsulation layer is provided outside the first pixel group 1 and the second pixel group 2. That is, both the first pixel group 1 and the second pixel group 2 are located within the encapsulation layer, thereby ensuring that the display panel 10 has better corrosion resistance, which is beneficial to prolonging a service life of the display panel 10.

A display apparatus according to another exemplary embodiment of the present disclosure includes the display panel 10 of any of the aforementioned exemplary embodiments. By providing the display panel 10, problems of jagged edge and colored edge in the display process can be eliminated, thereby ensuring the better display effect of the display apparatus.

In descriptions of this specification, descriptions of reference terms “an embodiment,” “some embodiments,” “an example,” “a specific example,” or “some examples” and the like mean that a particular feature, a structure, a material, or a characteristic described in conjunction with the embodiment or the example is included in at least one embodiment or example of the present disclosure. In this specification, a schematic expression of the above terms does not necessarily refer to the same embodiment or example. Moreover, the specific features, structures, materials, or characteristics described may be combined in any one or more embodiments or examples in a proper way. Further, those skilled in the art may incorporate and combine different embodiments or examples described in this specification.

Although the embodiments of the present disclosure have been shown and described above, it should be understood that the above embodiments are exemplary, and cannot be understood as limitation on the present disclosure. Changes, modifications, substitutions and variations to the above embodiments may be made by those skilled in the art within the scope of the present disclosure. The changes, modifications, substitutions and variations are within the protection scope of the present disclosure.

1. A display panel, a display area of the display panel comprising:
an irregular display region, wherein the irregular display region comprises a first pixel group, the first pixel group at least comprises an irregular sub-pixel, the irregular sub-pixel comprises an irregular sub-pixel edge, and the irregular sub-pixel edge is matched with an irregular edge of the irregular display region; and
a non-irregular display region, wherein the non-irregular display region comprises at least one second pixel group, and the second pixel group comprises a plurality of regular sub-pixels.

2. The display panel according to claim 1, wherein the irregular sub-pixel edge is parallel to the irregular edge of the irregular display region.

3. The display panel according to claim 1, wherein the first pixel group comprises a first irregular sub-pixel and a second irregular sub-pixel,
the first irregular sub-pixel and the second irregular sub-pixel are sequentially arranged along a first direction, a maximum width of the first irregular sub-pixel in the first direction is greater than a maximum width of the second irregular sub-pixel in the first direction, and a maximum length of the first irregular sub-pixel in a second direction is less than a maximum length of the second irregular sub-pixel in the second direction.

4. The display panel according to claim 3, wherein light emitting areas of the first irregular sub-pixel and the second irregular sub-pixel are identical.

5. The display panel according to claim 3, wherein light emitting colors of the first irregular sub-pixel and the second irregular sub-pixel are different from each other.

6. The display panel according to claim 3, wherein the first pixel group further comprises a third regular sub-pixel,
the first irregular sub-pixel, the second irregular sub-pixel, and the third regular sub-pixel are sequentially arranged along the first direction, a maximum width of the third regular sub-pixel in the first direction is less than maximum widths of the first irregular sub-pixel and the second irregular sub-pixel in the first direction, and a maximum length of the third regular sub-pixel in the second direction is greater than maximum lengths of the first irregular sub-pixel and the second irregular sub-pixel in the second direction.

7. The display panel according to claim 6, wherein light emitting areas of the first irregular sub-pixel, the second irregular sub-pixel, and the third regular sub-pixel are identical.

8. The display panel according to claim 6, wherein light emitting colors of the first irregular sub-pixel, the second irregular sub-pixel, and the third regular sub-pixel are different from each other.

9. The display panel according to claim 6, wherein at least two of the first irregular sub-pixel, the second irregular sub-pixel, and the third regular sub-pixel have different configurations.

10. The display panel according to claim 1, further comprising a filter layer, wherein
the first pixel group comprises a first irregular sub-pixel and a second irregular sub-pixel, the first irregular sub-pixel and the second irregular sub-pixel are sequentially arranged along a first direction, a maximum width of the first irregular sub-pixel in the first direction is identical to a maximum width of the second irregular sub-pixel in the first direction, and a maximum length of the first irregular sub-pixel in a second direction is less than a maximum length of the second irregular sub-pixel in the second direction;
the filter layer comprises a first irregular sub-pixel filter corresponding to the first irregular sub-pixel and a second irregular sub-pixel filter corresponding to the second irregular sub-pixel, a maximum width of the first irregular sub-pixel filter in the first direction is greater than a maximum width of the second irregular sub-pixel filter in the first direction, and a maximum length of the first irregular sub-pixel filter in the second direction is less than a maximum length of the second irregular sub-pixel filter in the second direction.

11. The display panel according to claim 10, wherein areas of the first irregular sub-pixel filter and the second irregular sub-pixel filter are identical.

12. The display panel according to claim 10, wherein the first pixel group further comprises a third regular sub-pixel,
the first irregular sub-pixel, the second irregular sub-pixel, and the third regular sub-pixel are sequentially arranged along the first direction, maximum widths of the first irregular sub-pixel, the second irregular sub-pixel and the third regular sub-pixel in the first direction are all identical, and a maximum length of the third regular sub-pixel in the second direction is greater than maximum lengths of the first irregular sub-pixel and the second irregular sub-pixel in the second direction;
the filter layer further comprises a third regular sub-pixel filter corresponding to the third regular sub-pixel, a maximum width of the third regular sub-pixel filter in the first direction is less than maximum widths of the first irregular sub-pixel filter and the second irregular sub-pixel filter in the first direction, and a maximum length of the third regular sub-pixel filter in the second direction is greater than maximum lengths of the first irregular sub-pixel filter and the second irregular sub-pixel filter in the second direction.

13. The display panel according to claim 12, wherein areas of the first irregular sub-pixel filter, the second irregular sub-pixel filter, and the third regular sub-pixel filter are identical.

14. The display panel according to claim 3, wherein a length of an irregular edge of the first irregular sub-pixel is greater than a maximum width of the first irregular sub-pixel in the first direction, and a length of an irregular edge of the second irregular sub-pixel is greater than a maximum width of the second irregular sub-pixel in the first direction.

15. The display panel according to claim 13, wherein the second pixel group comprises a fourth regular sub-pixel, a fifth regular sub-pixel, and a sixth regular sub-pixel,
maximum widths of the fourth regular sub-pixel, the fifth regular sub-pixel, and the sixth regular sub-pixel in the first direction are all identical, and maximum lengths of the fourth regular sub-pixel, the fifth regular sub-pixel and the sixth regular sub-pixel in the second direction are all identical.

16. The display panel according to claim 15, wherein light emitting colors of the first irregular sub-pixel, the second irregular sub-pixel, the third regular sub-pixel, the fourth regular sub-pixel, the fifth regular sub-pixel, and the sixth regular sub-pixel are formed by covering corresponding sub-pixels with filters of corresponding colors.

17. The display panel according to claim 16, wherein
a light emitting color of the first irregular sub-pixel is formed by covering the first irregular sub-pixel with the first irregular sub-pixel filter;
a light emitting color of the second irregular sub-pixel is formed by covering the second irregular sub-pixel with the second irregular sub-pixel filter; and
a light emitting color of the third regular sub-pixel is formed by covering the third regular sub-pixel with the third regular sub-pixel filter.

18. The display panel according to claim 15, wherein
the first irregular sub-pixel and the fourth regular sub-pixel are sub-pixels with the same light emitting color;
the second irregular sub-pixel and the fifth regular sub-pixel are sub-pixels with the same light emitting color; and
the third regular sub-pixel and the sixth regular sub-pixel are sub-pixels with the same light emitting color.

19. The display panel according to claim 18, wherein
the light emitting color of the first irregular sub-pixel and the fourth regular sub-pixel is a first color of three primary colors;
the light emitting color of the second irregular sub-pixel and the fifth regular sub-pixel is a second color of the three primary colors; and
the light emitting color of the third regular sub-pixel and the sixth regular sub-pixel is a third color of the three primary colors.

20. A display apparatus, comprising the display panel according to claim 1.
